(19) United States
(12) Patent Application Publication
(10) Pub. No.: US 2025/0289926 A1
(43) Pub. Date: Sep. 18, 2025

(54) CURABLE COMPOSITION FOR INSULATING FILM FORMATION, INSULATING FILM FORMATION METHOD, AND TERMINALLY MALEIMIDE-MODIFIED POLYPHENYLENE ETHER RESIN

(71) Applicant: TOKYO OHKA KOGYO CO., LTD., Kawasaki-shi (JP)

(72) Inventor: Kazuaki Ebisawa, Kawasaki-shi (JP)

(21) Appl. No.: 19/222,183

(22) Filed: May 29, 2025

Related U.S. Application Data
(62) Division of application No. 17/630,033, filed on Jan. 25, 2022.

(30) Foreign Application Priority Data
Aug. 20, 2019 (JP) 2019-150664

(51) Int. Cl. C08G 65/48; G03F 7/038; G03F 7/20

(52) U.S. Cl. CPC C08G 65/48; G03F 7/038; G03F 7/20

(57) ABSTRACT

A curable composition that is suitable for forming an insulating film, the curable composition having excellent film formation properties and making it possible to form a cured product that has a low dielectric constant and dielectric loss tangent but excellent heat resistance; an insulating film formation method that uses the curable composition; and a terminally maleimide-modified polyphenylene ether resin that is suitable as a component of the curable composition. The curable composition includes a terminally maleimide-modified polyphenylene ether resin that has, at a terminus of the molecular chain thereof, a radically polymerizable group that has a specific structure that includes a maleimide skeleton; and a radical generator.

### CROSS-REFERENCE TO RELATED APPLICATIONS

This application is a divisional of U.S. patent application Ser. No. 17/630,033, filed Jan. 25, 2022, which is the U.S. National Phase under 35 U.S.C. § 371 of International Application PCT/JP2020/026477, filed Jul. 6, 2020, designating the U.S., and published in Japanese as WO 2021/033442 on Feb. 5, 2021 which claims priority to Japanese Patent Application No. 2019-150664, filed Aug. 20, 2019, the entire contents of which are incorporated herein by reference.

### TECHNICAL FIELD

The present invention relates to a curable composition that is used to form an insulating film, a method for forming an insulating film, and a terminally maleimide-modified polyphenylene ether resin.

### BACKGROUND ART

In recent years, higher frequencies have been increasingly used in communication equipment such as mobile phones. Consequently, an insulating film that insulates metal wiring in the communication equipment is required to respond to higher frequencies.

Here, a transmission loss increases as a frequency increases, and an electrical signal attenuates as a transmission loss increases. Thus, reduction in transmission loss is required to respond to higher frequencies.

To reduce transmission loss, a technique of forming an insulating film using a material having a low dielectric constant and a low dielectric loss tangent is disclosed (e.g., Patent Literature 1).
Patent Document 1: Japanese Unexamined Patent Application, Publication No. 2004-87639

### DISCLOSURE OF THE INVENTION

### Problems to be Solved by the Invention

However, the technique of Patent Literature 1 is a technique using a resin composition having a specific structure, and specifically, it is a technique using a resin composition containing a cross-linking component represented by the formula (1) described in Patent Literature 1. In view of such a situation, a technique using other compositions other than the composition described in Patent Literature 1 is required.

The response to higher frequencies has also been required in network related electronic equipment such as servers, electronic equipment such as computers, and electrical and electronic devices other than the communication equipment.

In the production of electrical and electronic devices, an insulating film is formed from the composition, and then members such as wiring are further formed by heating, in many cases. Accordingly, heat resistance is also required for the insulating film.

When an insulating film is formed from a composition, the insulating film can be easily formed by a coating method. Accordingly, it is desired that the composition be applicable to coating, that is, the composition has excellent film formation properties by coating.

The present invention has been made in view of the above problems and an object thereof is to provide a curable composition suitably applicable to the formation of an insulating film, the curable composition being capable of forming a cured product having a low dielectric constant and a low dielectric loss tangent as well as excellent heat resistance, and having excellent film formation properties, a method for forming an insulating film using the curable composition, and a terminally maleimide-modified polyphenylene ether resin suitably used as a component of the curable composition.

### Means for Solving the Problems

The present inventors have found that a curable composition including a terminally maleimide-modified polyphenylene ether resin (A) having, at a terminal of a molecular chain, a radically polymerizable group having a specific structure including a maleimide skeleton not only provides an insulating film having a low dielectric constant and a low dielectric loss tangent as well as excellent heat resistance, but also has excellent film formation properties, thereby completing the present invention.

A first aspect of the present invention relates to a curable composition including a terminally maleimide-modified polyphenylene ether resin (A) and a radical generator (C),
the terminally maleimide-modified polyphenylene ether resin (A) having, at a terminal of a molecular chain, a terminal group represented by the following formula (a1):

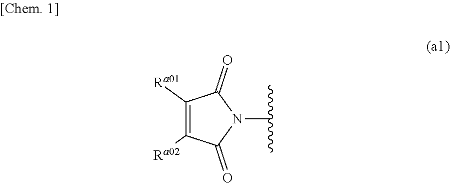

wherein R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms;
a phenylene group included in a main chain of the terminally maleimide-modified polyphenylene ether resin (A) optionally having 1 or more and 4 or less substituents;
the terminal group being bonded to the main chain of the terminally maleimide-modified polyphenylene ether resin (A) via a linking group represented by the following formula (a2):

$$⋆ - {Y}^{2} - {Y}^{1} - ⋆ ⋆ \qquad ( a2 )$$

wherein the bond on the ** side in the linking group is bonded to an oxygen atom derived from a hydroxyl group at a terminal of a molecular chain of an unmodified polyphenylene ether resin (A′) yielding the terminally maleimide-modified polyphenylene ether resin (A),
the bond on the * side in the linking group is bonded to the terminal group, and
Y¹ is a single bond or a carbonyl group, Y² is a divalent organic group, and when Y¹ is a single bond, the single bond as Y¹ is bonded to a carbon atom having an sp3 hybrid orbital in the divalent organic group as Y²; and
the curable composition being used to form an insulating film.

The second aspect of the present invention is a curable composition including a terminally maleimide-modified polyphenylene ether resin (A) and a radical generator (C),
the terminally maleimide-modified polyphenylene ether resin (A) having, at a terminal of a molecular chain, a terminal group represented by the following formula (a1):

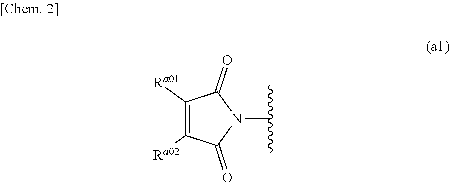

wherein R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms;
a phenylene group included in a main chain of the terminally maleimide-modified polyphenylene ether resin (A) optionally having 1 or more and 4 or less substituents; and
the radical generator (C) being a photoradical generator (C1).

The third aspect of the present invention is a terminally maleimide-modified polyphenylene ether resin having, at a terminal of a molecular chain, a terminal group represented by the following formula (a1):

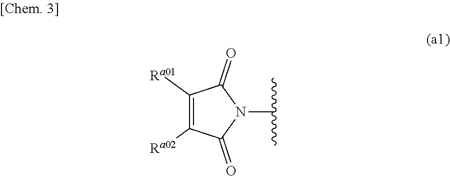

wherein R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms;
a phenylene group included in a main chain of the terminally maleimide-modified polyphenylene ether resin (A) optionally having 1 or more and 4 or less substituents; and
the terminal group being bonded to the main chain of the terminally maleimide-modified polyphenylene ether resin (A) via a linking group represented by the following formula (a2):

$$⋆ - {Y}^{2} - {Y}^{1} - ⋆ ⋆ \qquad ( a2 )$$

wherein the bond on the ** side in the linking group is bonded to an oxygen atom derived from a hydroxyl group at a terminal of a molecular chain of an unmodified polyphenylene ether resin (A′) yielding the terminally maleimide-modified polyphenylene ether resin (A),
the bond on the * side in the linking group is bonded to the terminal group, and
Y¹ is a single bond or a carbonyl group, Y² is a divalent organic group, and when Y¹ is a single bond, the single bond as Y¹ is bonded to a carbon atom having an sp3 hybrid orbital in the divalent organic group as Y².

### Effects of the Invention

The present invention can provide a curable composition suitably applicable to the formation of an insulating film, the curable composition being capable of forming a cured product that has a low dielectric constant and dielectric loss tangent as well as excellent heat resistance and having excellent film formation properties, a method for forming an insulating film using the curable composition, and a terminally maleimide-modified polyphenylene ether resin suitably used as a component of the curable composition.

### BRIEF DESCRIPTION OF THE DRAWINGS

FIG. 1 is a chart showing 1H NMR measurement results of the terminally maleimide-modified polyphenylene ether resin P1 obtained in Preparation Example 1 and an unmodified polyphenylene ether resin (SA90).

### PREFERRED MODE FOR CARRYING OUT THE INVENTION

### <Curable Composition>

Examples of the curable composition include a first curable composition and a second curable composition, which have common characteristics in that:
a terminally maleimide-modified polyphenylene ether resin (A) and a radical generator (C) are included,
the terminally maleimide-modified polyphenylene ether resin (A) having, at a terminal of a molecular chain, a terminal group represented by the following formula (a1):

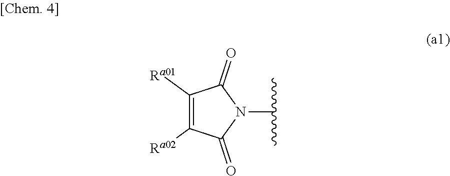

wherein R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms, and
a phenylene group included in the main chain of the terminally maleimide-modified polyphenylene ether resin (A) may have 1 or more and 4 or less substituents.

Hereinafter, the first curable composition and the second curable composition will be described.

### <First Curable Composition>

The first curable composition is a curable composition including the terminally maleimide-modified polyphenylene ether resin (A) and the radical generator (C).

As mentioned above, the terminally maleimide-modified polyphenylene ether resin (A) has the terminal group represented by the following formula (a1):

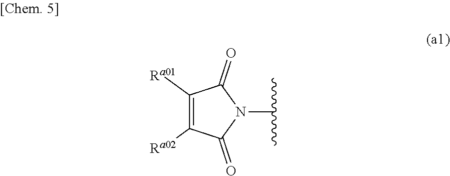

at a terminal of the molecular chain.

In the formula (a1), R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms.

The phenylene group included in the main chain of the terminally maleimide-modified polyphenylene ether resin (A) may have 1 or more and 4 or less substituents.

In the terminally maleimide-modified polyphenylene ether resin used in the first curable composition, the above terminal group is bonded to the main chain of the terminally maleimide-modified polyphenylene ether resin (A) via a linking group represented by the following formula (a2):

$$⋆ - {Y}^{2} - {Y}^{1} - ⋆ ⋆ . \qquad ( a2 )$$

The bond on the ** side in the linking group is bonded to an oxygen atom derived from a hydroxyl group at a terminal of the molecular chain of an unmodified polyphenylene ether resin (A′) that yields the terminally maleimide-modified polyphenylene ether resin (A). On the other hand, the bond on the * side in the linking group is bonded to the terminal group.

In the formula (a2), Y¹ is a single bond or a carbonyl group. Y² is a divalent organic group. When Y¹ is a single bond, the single bond as Y¹ is bonded to a carbon atom having an sp3 hybrid orbital in the divalent organic group as Y².

The first curable composition is used to form an insulating film. Typically, the first curable composition is used in electrical and electronic devices having metal wiring to form an insulating film that insulates metal wiring.

The electrical and electronic devices are not particularly limited, and examples thereof include communication equipment such as mobile phones, network related electronic equipment such as servers, electronic equipment such as computers, in particular, semiconductor components included in the equipment, and specifically, a semiconductor package referred to as a wafer level package.

These electrical and electronic devices have metal wiring made of a metal such as copper and an alloy on a substrate for electrical and electronic devices. Examples of the substrate for electrical and electronic devices having metal wiring include a silicon substrate and a substrate having various layers and members on a silicon substrate. This metal wiring and another metal wiring or conductive member are insulated by an insulating film formed from the first curable composition.

By using the first curable composition including the components described below, an insulating film having a low dielectric constant and a low dielectric loss tangent (tan δ) can be formed. Thus, the first curable composition including the components described below is suitable as the insulating film that insulates the metal wiring of electrical and electronic devices using high frequency signals. Note that as used herein, the “high frequency” means a frequency of 3 GHZ or more. Since an insulating film having excellent heat resistance can be formed, for example, the first curable composition can be used to form an insulating film in electrical and electronic devices in which an insulating film is formed from a curable composition and then other members are formed by heating.

Further, the first curable composition has excellent film formation properties by coating. That is, when a film is formed by coating, no crack and no crystal are generated, no tackiness (stickiness) is present, and the compatibility of the components is good, and thus an insulating film can be formed by coating which is an easy method.

Hereinafter, the first curable composition will be described in detail.

### [Terminally Maleimide-Modified Polyphenylene Ether Resin (A)]

The first curable composition contains the terminally maleimide-modified polyphenylene ether resin (A) having the terminal group represented by the following formula (a1) at a terminal of the molecular chain.

Note that in the specification of the present application, the substituted or unsubstituted cyclic imido group represented by the formula (a1) is also referred to as the “maleimide group” for convenience.

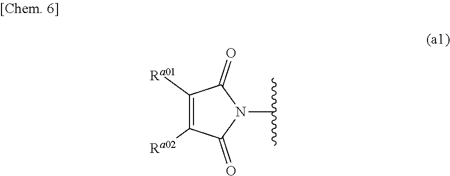

In the formula (a1), R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms.

The alkyl group having 1 or more and 6 or less carbon atoms as R^{a01} and R^{a02} in the formula (a1) may be a linear alkyl group or a branched alkyl group. Specific examples thereof include a methyl group, an ethyl group, a n-propyl group, a n-butyl group, a n-pentyl group, a n-hexyl group, an isopropyl group, an isobutyl group, a sec-butyl group, a tert-butyl group, an isopentyl group, a neopentyl group, a tert-pentyl group, and an isohexyl group.

Specific examples of the cycloalkyl group having 3 or more and 8 or less carbon atoms as R^{a01} and R^{a02} in the formula (a1) include a cyclopropyl group, a cyclobutyl group, a cyclopentyl group, and a cyclohexyl group.

Specific examples of the aryl group having 6 or more and 12 or less carbon atoms as R^{a01} and R^{a02} in the formula (a1) include a phenyl group, a biphenyl group, a 1-naphthyl group, and a 2-naphthyl group.

Both R^{a01} and R^{a02} in the formula (a1) are preferably a hydrogen atom. When both R^{a01} and R^{a02} are a hydrogen atom, the terminally maleimide-modified polyphenylene ether resin (A) has excellent polymerization properties. Thus, the first curable composition having excellent curing properties is easily obtained. When both R^{a01} and R^{a02} are a hydrogen atom, the group represented by the formula (a1) is an unsubstituted maleimide group.

The terminal group represented by the formula (a1) is bonded to the main chain of the terminally maleimide-modified polyphenylene ether resin (A) via the linking group represented by the following formula (a2):

$$⋆ - {Y}^{2} - {Y}^{1} - ⋆ ⋆ . \qquad ( a2 )$$

The above bond on the ** side in the linking group is bonded to an oxygen atom derived from a hydroxyl group at a terminal of the molecular chain of the unmodified polyphenylene ether resin (A′) that yields the terminally maleimide-modified polyphenylene ether resin (A). On the other hand, the bond on the * side in the linking group is bonded to the terminal group represented by the formula (a1).

In the formula (a2), Y¹ is a single bond or a carbonyl group. Y² is a divalent organic group. When Y¹ is a single bond, the single bond as Y¹ is bonded to a carbon atom having an sp3 hybrid orbital in the divalent organic group as Y².

When Y¹ is a carbonyl group in the formula (a2), Y² is preferably a group represented by —Y⁴—Y³—. Y³ is a single bond, —O—, or —NH—. Y⁴ is preferably a divalent organic group. Y³ is bonded to a carbonyl group as Y¹. That is, when Y¹ in the formula (a2) is a carbonyl group, the linking group represented by the formula (a2) is preferably a group represented by the following formulas (a2-1) to (a2-3).

$$⋆ - {Y}^{4} - C O - ⋆ ⋆ \qquad ( a2 - 1 )$$

$$⋆ - {Y}^{4} - O - C O - ⋆ ⋆ \qquad ( a2 - 2 )$$

$$⋆ - {Y}^{4} - N H - C O - ⋆ ⋆ \qquad ( a2 - 3 )$$

The divalent organic group as Y⁴ is not particularly limited, as long as it is a group capable of linking Y³ with the terminal group represented by the formula (a1). The structure of the organic group may be linear, branched, cyclic, or a combination of these structures. Examples of a heteroatom other than a carbon atom and a hydrogen atom that may be contained in the organic group include a nitrogen atom, a sulfur atom, an oxygen atom, a halogen atom, a phosphorus atom, a silicon atom, and a boron atom. The organic group may have one or more unsaturated bonds.

Since, for example, a compound used in the terminal modification of the terminally maleimide-modified polyphenylene ether resin (A) is easily available or produced and the desired terminal modification is easily achieved, Y⁴ is preferably a hydrocarbon group.

The number of carbon atoms in the hydrocarbon group is preferably 1 or more and 10 or less, more preferably 1 or more and 8 or less, and further preferably 1 or more and 6 or less.

The hydrocarbon group may be an aliphatic hydrocarbon group or an aromatic hydrocarbon group. The hydrocarbon group is preferably an aliphatic hydrocarbon group, which is flexible as compared with a rigid aromatic hydrocarbon group.

Examples of the hydrocarbon group that is preferred as Y⁴ include a methylene group, an ethane-1,2-diyl group, an ethane-1,1-diyl group, a propane-1,3-diyl group, a propane-1,2-diyl group, a propane-1,1-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, a cyclohexane-1,4-diyl group, a cyclohexane-1,3-diyl group, a cyclohexane-1,2-diyl group, a p-phenylene group, a m-phenylene group, an o-phenylene group, a naphthalene-1,4-diyl group, a naphthalene-2,6-diyl group, and a naphthalene-2,7-diyl group.

Among these, an ethane-1,2-diyl group, a propane-1,3-diyl group, a butane-1,4-diyl group, a cyclohexane-1,4-diyl group, and a cyclohexane-1,3-diyl group are preferable.

When Y¹ is a single bond in the formula (a2), the single bond as Y¹ is bonded to a carbon atom having an sp3 hybrid orbital in the divalent organic group as Y². Typically, the carbon atom having an sp3 hybrid orbital is the carbon atom that constitutes an entire structure or partial structure consisting of an aliphatic hydrocarbon group, in the organic group as Y².

When Y¹ is a single bond in the formula (a2), the divalent organic group as Y² is not particularly limited, as long as it is a group having at least one carbon atom having an sp3 hybrid orbital and capable of linking an oxygen atom derived from a hydroxyl group at a terminal of the molecular chain of the unmodified polyphenylene ether resin (A′) that yields the terminally maleimide-modified polyphenylene ether resin (A) with the terminal group represented by the formula (a1). The divalent organic group as Y² when Y¹ is a single bond may include one or more heteroatoms such as a nitrogen atom, a sulfur atom, an oxygen atom, a halogen atom, a phosphorus atom, a silicon atom, and a boron atom, other than a carbon atom and a hydrogen atom.

When Y¹ is a single bond, the number of carbon atoms of the divalent organic group as Y² is preferably 1 or more and 10 or less, more preferably 1 or more and 8 or less, and further preferably 1 or more and 6 or less.

When Y¹ is a single bond, the divalent organic group as Y² is preferably an aliphatic hydrocarbon group in which one or more methylene groups may be substituted with a carbonyl group (—CO—), an ether bond (—O—), or an imino group (—NH—). When Y¹ is a single bond, preferable examples of the aliphatic hydrocarbon group as Y² include a methylene group, an ethane-1,2-diyl group, an ethane-1,1-diyl group, a propane-1,3-diyl group, a propane-1,2-diyl group, a propane-1,1-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, a cyclohexane-1,4-diyl group, a cyclohexane-1,3-diyl group, and a cyclohexane-1,2-diyl group. Groups in which one or two methylene groups included in these hydrocarbon groups are substituted with a carbonyl group (—CO—), an ether bond (—O—), or an imino group (—NH—) are also preferable.

Among these, an ethane-1,2-diyl group, a propane-1,3-diyl group, a butane-1,4-diyl group, a cyclohexane-1,4-diyl group, and a cyclohexane-1,3-diyl group are preferable.

The method for introducing the terminal group represented by the formula (a1) at a terminal of the molecular chain of the unmodified polyphenylene ether resin (A′) to modify the resin is not particularly limited.

To carry out such a modification, the unmodified polyphenylene ether resin (A′) having a phenolic hydroxyl group terminal is preferably used.

The unmodified polyphenylene ether resin (A′) is only required to be a resin having at least one phenolic hydroxyl group terminal. The unmodified polyphenylene ether resin (A′) preferably has two or more phenolic hydroxyl group terminals, more preferably two or three phenolic hydroxyl group terminals, and further preferably two phenolic hydroxyl group terminals. When the unmodified polyphenylene ether resin (A′) has a phenolic hydroxyl group at a terminal, the unmodified polyphenylene ether resin (A′) may further have a phenolic hydroxyl group on the phenylene group included in the main chain.

Typically, the polyphenylene ether resin may be produced by oxidatively polymerizing a phenolic compound such as 2,6-dimethylphenol in the presence of a catalyst including a metal such as copper. The production method of the unmodified polyphenylene ether resin (A′) is not particularly limited, but the unmodified polyphenylene ether resin (A′) is preferably produced according to a publicly known method, that is, according to the aforementioned typical method.

The phenylene group included in the main chain of the terminally maleimide-modified polyphenylene ether resin (A) may have 1 or more and 4 or less substituents. Thus, the phenylene group included in the main chain of the unmodified polyphenylene ether resin (A′) may have 1 or more and 4 or less substituents. Preferable examples of the substituent include an alkyl group having 1 or more and 4 or less carbon atoms such as a methyl group, an ethyl group, a n-propyl group, an isopropyl group, a n-butyl group, an isobutyl group, a sec-butyl group, and a tert-butyl group; an aromatic hydrocarbon group such as a phenyl group, an o-tolyl group, a m-tolyl group, and a p-tolyl group; an alkoxy group having 1 or more and 4 or less carbon atoms such as a methoxy group, an ethoxy group, a n-propyloxy group, an isopropyloxy group, a n-butyloxy group, an isobutyloxy group, a sec-butyloxy group, and a tert-butyloxy group; a phenolic hydroxyl group; and a halogen atom such as a fluorine atom, a chlorine atom, a bromine atom, and an iodine atom. Among these substituents, a methyl group, a phenyl group, a chlorine atom, and a bromine atom are preferable, and a methyl group, a phenyl group, and a chlorine atom are more preferable.

Examples of the unmodified polyphenylene ether resin (A′) include homopolymers of phenols or copolymers of two or more phenols.

The unmodified polyphenylene ether resin (A′) may be a polymer obtained by polymerizing only a monohydric phenol, or may be a polymer obtained by copolymerizing a monohydric phenol and a polyhydric phenol such as a dihydric phenol and a trihydric phenol.

The polymer made of only a monohydric phenol has an aryl group derived from a raw material phenol having no hydroxyl group at one terminal, and a hydroxyaryl group derived from a raw material phenol at the other terminal.

In the copolymer of a monohydric phenol and a polyhydric phenol, the molecular chain of polyphenylene ether grows from two or more phenolic hydroxyl groups in the polyhydric phenol as a starting point. Thus, when a monohydric phenol is copolymerized with a dihydric phenol, a polyphenylene ether resin having hydroxyaryl groups at both terminals is obtained. When a monohydric phenol is copolymerized with a trihydric or higher phenol, a polyphenylene ether resin having branched chains corresponding to the valence of the polyhydric phenol and having a hydroxyaryl group at the terminal of each branched chain is obtained.

Specific examples of the homopolymer of phenols include poly(2,6-dimethyl-1,4-phenylene ether), poly(2-methyl-6-phenyl-1,4-phenylene ether), and poly(2,6-dichloro-1,4-phenylene ether).

As mentioned above, the copolymer of two or more phenols may be a copolymer of two or more monohydric phenols, or a copolymer of one or more monohydric phenols and one or more dihydric phenols.

Specific examples of the copolymer of two or more monohydric phenols include a copolymer of 2,6-dimethylphenol and 2,3,6-trimethylphenol, a copolymer of 2,6-dimethylphenol and 2,6-dichlorophenol, and a copolymer of 2,6-dimethylphenol and 2-methyl-6-phenylphenol.

Examples of the copolymer of one or more monohydric phenols and one or more dihydric phenols include a copolymer obtained by polymerizing 2,6-dimethylphenol with 3,3′,5,5′-tetramethyl bisphenol A, a copolymer obtained by polymerizing 2-methyl-6-phenylphenol with 3,3′,5,5′-tetramethyl bisphenol A, and a copolymer obtained by polymerizing 2,6-dichlorophenol with 3,3′,5,5′-tetramethyl bisphenol A.

As the unmodified polyphenylene ether resin (A′), the copolymer obtained by polymerizing 2,6-dimethylphenol with 3,3′,5,5′-tetramethyl bisphenol A, the copolymer obtained by polymerizing 2-methyl-6-phenylphenol with 3,3′,5,5′-tetramethyl bisphenol A, and the copolymer obtained by polymerizing 2,6-dichlorophenol with 3,3′,5,5′-tetramethyl bisphenol A, of which are the copolymers of a monohydric phenol and a dihydric phenol, are preferable, and the copolymer obtained by polymerizing 2,6-dimethylphenol with 3,3′,5,5′-tetramethyl bisphenol A is more preferable.

The method for modifying the unmodified polyphenylene ether resin (A′) and introducing the terminal group represented by the formula (a1) at the terminal is not particularly limited.

For example, when Y¹ is a carbonyl group in the formula (a2) and the linking group represented by the formula (a2) is a group represented by the following formula (a2-1):

$$⋆ - {Y}^{4} - C O - ⋆ ⋆ , \qquad ( a2 - 1 )$$

a carboxylic acid represented by MIG-Y⁴—CO—OH and the phenolic hydroxyl group included in the unmodified polyphenylene ether resin (A′) are condensed with a condensing agent such as a carbodiimide compound such as carbonyldiimidazole and N,N′-diisopropylcarbodiimide, so that the terminal phenolic hydroxyl group included in the unmodified polyphenylene ether resin (A′) can be converted to a group represented by —O—CO—Y⁴-MIG. Note that MIG is the terminal group represented by the formula (a1).

Also, a carboxylic acid halide represented by MIG-Y⁴—CO-Hal is reacted with the phenolic hydroxyl group included in the unmodified polyphenylene ether resin (A′), so that the terminal phenolic hydroxyl group included in the unmodified polyphenylene ether resin (A′) can be converted to the group represented by —O—CO—Y⁴-MIG. Note that Hal is a halogen atom such as a chlorine atom and a bromine atom.

When Y¹ is a carbonyl group in the formula (a2) and the linking group represented by the formula (a2) is a group represented by the following formula (a2-2):

$$⋆ - {Y}^{4} - O - C O - ⋆ ⋆ , \qquad ( a2 - 2 )$$

the phenolic hydroxyl group included in the unmodified polyphenylene ether resin (A′) and an alcohol represented by MIG-Y⁴—OH in an excess amount relative to the phenolic hydroxyl group are reacted with a compound that produces a carbonate bond such as phosgene and triphosgene, so that the terminal phenolic hydroxyl group included in the unmodified polyphenylene ether resin (A′) can be converted to a group represented by —O—CO—O—Y⁴-MIG.

When Y¹ is a carbonyl group in the formula (a2), and a linking group represented by the formula (a2-3) is a group represented by the following formula (a2-3):

$$⋆ - {Y}^{4} - N H - C O - ⋆ ⋆ , \qquad ( a2 - 3 )$$

the phenolic hydroxyl group included in the unmodified polyphenylene ether resin (A′) is reacted with an isocyanate represented by MIG-Y⁴—NCO, so that the terminal phenolic hydroxyl group included in the unmodified polyphenylene ether resin (A′) can be converted to a group represented by —O—Co—NH—Y⁴-MIG.

When Y¹ is a single bond in the formula (a2), the phenolic hydroxyl group included in the unmodified polyphenylene ether resin (A′) and a halide represented by MIG-Y²-Hal are etherified by a method such as the so-called Williamson ether synthesis, so that the terminal phenolic hydroxyl group included in the unmodified polyphenylene ether resin (A′) can be converted to a group represented by —O—Y²-MIG.

Hereinbefore, representative methods for modifying the phenolic hydroxyl group are described, but the method for modifying the phenolic hydroxyl group is not limited to these methods. As the method for modifying the phenolic hydroxyl group, various known methods may be employed according to the structure of the linking group bonded to the terminal group represented by the formula (a1).

In the above modification methods, an organic solvent may be appropriately used according to the reaction employed, as needed. Also, with respect to the reaction temperature and the reaction time, known suitable conditions in the reaction employed may be appropriately employed.

When the terminally maleimide-modified polyphenylene ether resin (A) is prepared using the unmodified polyphenylene ether resin (A′), a group including the terminal group represented by the formula (a1) may be introduced into some of the phenolic hydroxyl groups included in the unmodified polyphenylene ether resin (A′) or a group including the terminal group represented by the formula (a1) may be introduced into all the phenolic hydroxyl groups.

The molecular weight of the terminally maleimide-modified polyphenylene ether resin (A) is not particularly limited, as long as the effect of the present invention is not impaired. The mass average molecular weight (Mw) is preferably 2,000 or more, more preferably 2, 500 or more, and further preferably 3,000 or more. The molecular weight of the resin (A) is preferably 100,000 or less, more preferably 80,000 or less, further preferably 50,000 or less, and further more preferably 10,000 or less as the mass average molecular weight (Mw).

As used herein, the mass average molecular weight (Mw) is a measured value in terms of polystyrene determined by gel permeation chromatography (GPC).

Thus, since the terminal group represented by the formula (a1) is a radically polymerizable group, the terminally maleimide-modified polyphenylene ether resin (A) having the terminal group represented by the formula (a1) at a specific position can be polymerized by exposure or heating. As a result of polymerization, the terminally maleimide-modified polyphenylene ether resin (A) yields an insulating film having a low dielectric constant and a low dielectric loss tangent as well as excellent heat resistance. For example, the dielectric constant of the insulating film to be formed may be less than 3.00. The dielectric loss tangent of the insulating film to be formed may be less than 0.01. The glass transition temperature (Tg) of the insulating film to be formed may be 150° C. or more.

The first curable composition including the terminally maleimide-modified polyphenylene ether resin (A) has excellent film formation properties by coating. Thus, when a film is formed by coating using such a curable composition, no crack and no crystal are generated, no tackiness (stickiness) is present, and the compatibility of the components is good. Thus, an insulating film can be formed by coating which is an easy method.

The terminally maleimide-modified polyphenylene ether resin (A) has excellent solvent solubility. Thus, the first curable composition including the terminally maleimide-modified polyphenylene ether resin (A) is applicable to a development process with a solvent, as a negative composition.

In particular, the terminally maleimide-modified polyphenylene ether resin (A) may be soluble in an alkaline aqueous solution, although it depends on its structure. An example thereof is a case where the terminally maleimide-modified polyphenylene ether resin (A) has an alkali-soluble group such as a carboxy group and a phenolic hydroxyl group. The first curable composition including such an alkali-soluble terminally maleimide-modified polyphenylene ether resin (A) is applicable to an alkali development process, as a negative composition.

By applying a position-selective exposure and the above development process to the coating film made of the first curable composition including the terminally maleimide-modified polyphenylene ether resin (A), an insulating film having a desired pattern shape can be formed.

The content of the terminally maleimide-modified polyphenylene ether resin (A) in the first curable composition is not particularly limited. The content of the terminally maleimide-modified polyphenylene ether resin (A) is preferably 5% by mass or more and 100% by mass or less based on the total solid content of the first curable composition.

### [Radically Polymerizable Compound (B)]

The first curable composition may further include the radically polymerizable compound (B). Of course, the first curable composition may not include the radically polymerizable compound (B).

The radically polymerizable compound (B) is a radically polymerizable compound other than the terminally maleimide-modified polyphenylene ether resin (A).

The radically polymerizable compound (B) may be a compound having an unsaturated double bond, such as styrene, a styrene polymer, acrylonitrile, (meth)acrylic acid, and a (meth)acrylic acid ester, but a radically polymerizable compound having the above group represented by the formula (a1) is preferable.

As the radically polymerizable compound having the above group represented by the formula (a1), a polyfunctional maleimide compound having two or more groups represented by the formula (a1) is preferable, and a bismaleimide compound in which two amino groups of an aromatic diamine or an aliphatic diamine are substituted with the group represented by the formula (a1) is preferable.

Specific examples of the aromatic diamine include p-phenylenediamine, m-phenylenediamine, 2,4-diaminotoluene, 4,4′-diaminobiphenyl, 4,4′-diamino-2,2′-bis(trifluoromethyl) biphenyl, 3,3′-diaminodiphenylsulfone, 4,4′-diaminodiphenylsulfone, 4,4′-diaminodiphenylsulfide, 4,4′-diaminodiphenylmethane, 4,4′-diaminodiphenyl ether, 3,4′-diaminodiphenyl ether, 3,3′-diaminodiphenyl ether, 1,4-bis(4-aminophenoxy)benzene, 1,3-bis(4-aminophenoxy)benzene, 1,3-bis(3-aminophenoxy)benzene, 4,4′-bis(4-aminophenoxy) biphenyl, bis[4-(4-aminophenoxy)phenyl]sulfone, bis[4-(3-aminophenoxy)phenyl]sulfone, 2,2-bis[4-(4-aminophenoxy)phenyl]propane, and 2,2-bis[4-(4-aminophenoxy)phenyl]hexafluoropropane.

Specific examples of the aliphatic diamine include pentamethylene diamine, hexamethylene diamine, heptamethylene diamine, and 2,3,3-trimethylpentane-1,5-diamine.

Examples of the radically polymerizable compound having the above group represented by the formula (a1) include 2,2-bis[4-(4-maleimidephenoxy)phenyl]propane, the following compounds (all manufactured by Tokyo Kasei Kogyo Co., Ltd.), and BMI-689, BMI-1400, BMI-1500, BMI-1700, BMI-2700, and BMI-3000 (all manufactured by Designer molecules Inc.).

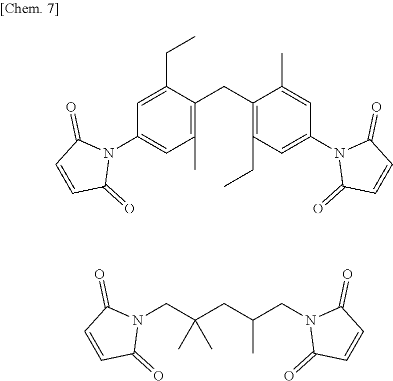 [SMILES: CCc1cc(N2C(=O)C=CC2=O)cc(C)c1Cc1c(C)cc(N2C(=O)C=CC2=O)cc1CC ; CC(CN1C(=O)C=CC1=O)CC(C)(C)CN1C(=O)C=CC1=O]

As the radically polymerizable compound other than the above maleimide compounds, various radically polymerizable compounds conventionally blended in the radically polymerizable compositions may be used without particular limitation. Specific examples of the radically polymerizable compounds other than the maleimide compound include the following compounds.

Examples of monofunctional radically polymerizable compounds include (meth)acrylamide, methylol (meth)acrylamide, methoxymethyl (meth)acrylamide, ethoxymethyl (meth)acrylamide, propoxymethyl (meth)acrylamide, butoxymethoxymethyl (meth)acrylamide, N-methylol (meth)acrylamide, N-hydroxymethyl (meth)acrylamide, (meth)acrylic acid, fumaric acid, maleic acid, maleic anhydride, itaconic acid, itaconic anhydride, citraconic acid, citraconic anhydride, crotonic acid, 2-acrylamide-2-methylpropanesulfonic acid, tert-butylacrylamidesulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerin mono(meth)acrylate, tetrahydrofurfuryl (meth)acrylate, dimethylamino (meth)acrylate, glycidyl (meth)acrylate, 2,2,2-trifluoroethyl (meth)acrylate, 2,2,3,3-tetrafluoropropyl (meth)acrylate, and half (meth)acrylate of a phthalic acid derivative. These monofunctional compounds may be used alone or in combination of two or more.

Examples of polyfunctional radically polymerizable compounds include 1,3-butanediol di(meth)acrylate, 1,4-butanediol di(meth)acrylate, 1,6-hexanediol di(meth)acrylate, 1,9-nonanediol di(meth)acrylate, 1,10-decanediol di(meth)acrylate, 1,12-dodecanediol di(meth)acrylate, ethoxylated hexanediol di(meth)acrylate, tricyclodecane dimethanol di(meth)acrylate, 2-hydroxy-3-(meth)acryloyloxypropyl (meth)acrylate, dipentaerythritol di(meth)acrylate, diethylene glycol di(meth)acrylate, triethylene glycol di(meth)acrylate, dipropylene glycol di(meth)acrylate, tripropylene glycol di(meth)acrylate, ethoxylated neopentyl glycol di(meth)acrylate, polyethylene glycol di(meth)acrylate, poly(ethylene-propylene) glycol di(meth)acrylate, polytetramethylene glycol di(meth)acrylate, ethoxylated bisphenol A di(meth)acrylate, propoxylated bisphenol A di(meth)acrylate, propoxylated ethoxylated bisphenol A di(meth)acrylate, ethylene glycol di(meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, glycerin di(meth)acrylate, pentaerythritol triacrylate, pentaerythritol tetraacrylate, dipentaerythritol pentaacrylate, dipentaerythritol hexaacrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, 2,2-bis(4-(meth)acryloxydiethoxyphenyl) propane, 2,2-bis(4-(meth)acryloxypolyethoxyphenyl) propane, 2-hydroxy-3-(meth)acryloyloxypropyl (meth)acrylate, ethylene glycol diglycidyl ether di(meth)acrylate, diethylene glycol diglycidyl ether di(meth)acrylate, phthalic acid diglycidyl ester di(meth)acrylate, glycerin triacrylate, glycerin polyglycidyl ether poly(meth)acrylate, urethane (meth)acrylate (that is, tolylene diisocyanate), a reactant of trimethylhexamethylene diisocyanate, hexamethylene diisocyanate, and the like with 2-hydroxyethyl (meth)acrylate, methylenebis (meth)acrylamide, (meth)acrylamide methylene ether, a condensate of a polyhydric alcohol and N-methylol (meth)acrylamide, triacrylformal, 2,4,6-trioxohexahydro-1,3,5-triazine-1,3,5-trisethanol triacrylate, and 2,4,6-trioxohexahydro-1,3,5-triazine-1,3,5-trisethanol diacrylate. These polyfunctional compounds may be used alone or in combination of two or more.

The content of the radically polymerizable compound (B) in the first curable composition is not particularly limited, but is preferably 10% by mass or more and 70% by mass or less, based on the total amount of the terminally maleimide-modified polyphenylene ether resin (A) and the radically polymerizable compound (B).

### [Radical Generator (C)]

The first curable composition includes the radical generator (C). The radical generator (C) may be a photoradical generator (C1) or a thermal radical generator (C2), and the photoradical generator (C1) and the thermal radical generator (C2) may be used in combination.

Examples of the photoradical generator (C1) include alkylphenone photoradical generators such as Omnirad 651, Omnirad 184, Omnirad 1173, Omnirad 2959, Omnirad 127, Omnirad 907, Omnirad 369, Omnirad 369E, and Omnirad 379EG (all of which are manufactured by IGM Resins B. V.), acylphosphine oxide photoradical generators such as Omnirad TPOH and Omnirad 819 (both are manufactured by IGM Resins B.V.), and oxime ester photopolymerization initiators such as Irgacure OXE01 and Irgacure OXE02 (both are manufactured by BASF).

Specific examples of the photoradical generator (C1) include 1-hydroxycyclohexyl phenyl ketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 1-(4-dodecylphenyl)-2-hydroxy-2-methylpropan-1-one, 2,2-dimethoxy-1,2-diphenylethan-1-one, bis(4-dimethylaminophenyl) ketone, 2-methyl-1-[4-(methylthio)phenyl]-2-morpholinopropan-1-one, 2-benzyl-2-dimethylamino-1-(4-morpholinophenyl)-butan-1-one, 1,2-octanedione, 1-[4-(phenylthio)phenyl]-, 2-(0-benzoyloxime) (Irgacure OXE01), ethanone-1-[9-ethyl-6-(2-methylbenzoyl)-9H-carbazol-3-yl]-1-(O-acetyloxime) (Irgacure OXE02), 2,4,6-trimethylbenzoyl diphenylphosphine oxide (Omnirad TPOH), bis(2,4,6-trimethylbenzoyl)phenylphosphine oxide (Omnirad 819), 4-benzoyl-4′-methyl dimethyl sulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-β-methoxyethyl acetal, benzyl dimethyl ketal, 1-phenyl-1,2-propanedione-2-(0-ethoxycarbonyl) oxime, methyl O-benzoylbenzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethylanthraquinone, 1,2-benzanthraquinone, 2,3-diphenylanthraquinone, azobisisobutyronitrile, benzoylperoxide, cumene hydroperoxide, 2-mercaptobenzimidazole, 2-mercaptobenzoxazole, 2-mercaptobenzothiazole, 2-(O-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, benzyl, benzoin, benzoin methyl ether, benzoin ethyl ether, benzoin isopropyl ether, benzoin-n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, a, a-dichloro-4-phenoxyacetophenone, thioxanthone, 2-methylthioxanthone, 2-isopropylthioxanthone, dibenzosuberone, pentyl-4-dimethylaminobenzoate, 9-phenylacridine, 1,7-bis-(9-acridinyl) heptane, 1,5-bis-(9-acridinyl) pentane, 1,3-bis-(9-acridinyl) propane, p-methoxytriazine, 2,4,6-tris(trichloromethyl)-s-triazine, 2-methyl-4,6-bis(trichloromethyl)-s-triazine, 2-[2-(5-methylfuran-2-yl) ethenyl]-4,6-bis(trichloromethyl)-s-triazine, 2-[2-(furan-2-yl) ethenyl]-4,6-bis(trichloromethyl)-s-triazine, 2-[2-(4-diethylamino-2-methylphenyl) ethenyl]-4,6-bis(trichloromethyl)-s-triazine, 2-[2-(3,4-dimethoxyphenyl) ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy) styrylphenyl-s-triazine, and 2,4-bis-trichloromethyl-6-(2-bromo-4-methoxy) styrylphenyl-s-triazine. These photoradical generators may be used alone or in combination of two or more. Among these, an oxime photoradical generator is particularly preferably used in terms of sensitivity.

Examples of the thermal radical generator (C2) include organic peroxides such as ketone peroxides (e.g., methyl ethyl ketone peroxide and cyclohexanone peroxide), peroxyketals (e.g., 2,2-bis(tert-butylperoxy) butane and 1,1-bis(tert-butylperoxy) cyclohexane), hydroperoxides (tert-butylhydroperoxide and cumene hydroperoxide), dialkyl peroxides (e.g., di-tert-butylperoxide (PERBUTYL(R) D (manufactured by NOF CORPORATION) and di-tert-hexyl peroxide (PERHEXYL(R) D (manufactured by NOF CORPORATION))), diacyl peroxides (e.g., isobutyrylperoxide, lauroylperoxide, and benzoylperoxide), peroxydicarbonates (e.g., diisopropylperoxydicarbonate), and peroxyesters (e.g., tert-butylperoxyisobutyrate and 2,5-dimethyl-2,5-di(benzoylperoxy)hexane)}, and azo compounds such as 1,1′-azobis(cyclohexane-1-carbonitrile), 2,2′-azobisisobutyronitrile, 2,2′-azobis(2,4-dimethyl-4-methoxyvaleronitrile), 2,2′-azobis(2-methylpropionamidine) dihydrochloride, 2,2′-azobis[2-methyl-N-(2-propenyl) propionamidine]dihydrochloride, 2,2′-azobis(2-methylpropionamide), 2,2′-azobis[2-methyl-N-(2-hydroxyethyl) propionamide], 2,2′-azobis(2-methylpropane), 2,2′-azobis(2,4,4-trimethylpentane), and dimethyl 2,2′-azobis(2-methylpropionate)}.

The content of the radical generator (C) in the first curable composition is not particularly limited, and is preferably 0.1 parts by mass or more and 10 parts by mass or less, more preferably 0.5 parts by mass or more and 10 parts by mass or less, and further preferably 2 parts by mass or more and 10 parts by mass or less, per 100 parts by mass in total of the terminally maleimide-modified polyphenylene ether resin (A) and the radically polymerizable compound (B).

### <Organic Solvent(S)>

The first curable composition usually includes the organic solvent(S). The type of the organic solvent(S) is not particularly limited within a range not inhibiting the purpose of the present invention, and may be appropriately selected and used from the organic solvents that are conventionally used in photosensitive compositions.

Specific examples of the organic solvent(S) include ketones such as acetone, methyl ethyl ketone, cyclohexanone, methyl isoamyl ketone, and 2-heptanone; polyhydric alcohols such as ethylene glycol, ethylene glycol monoacetate, diethylene glycol, diethylene glycol monoacetate, propylene glycol, propylene glycol monoacetate, propylene glycol monomethyl ether acetate, dipropylene glycol, dipropylene glycol monoacetate monomethyl ether, monoethyl ether, monopropyl ether, monobutyl ether, monophenyl ether, and derivatives thereof; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, ethyl pyruvate, ethyl ethoxyacetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanoate, 3-methoxybutyl acetate, and 3-methyl-3-methoxybutyl acetate; and aromatic organic solvents such as heteroatom-containing aromatic compounds (e.g., anisole) and aromatic hydrocarbons (e.g., toluene and xylene). These may be used alone or in combination of two or more.

The content of the organic solvent(S) is not particularly limited within a range not inhibiting the purpose of the present invention. The organic solvent(S) is preferably used within a range in which the solid concentration of the first curable composition is 30% by mass or more and 70% by mass or less.

### [Other Additives]

The first curable composition may further contain a maleimide curing agent (E) to improve curing properties, and may further contain a surfactant to improve coating properties, defoaming properties, leveling properties, and the like.

Examples of the maleimide curing agent include diamines; allyl compounds such as low-polarity polyfunctional allylphenol resin (e.g., FATC (manufactured by Gunei Chemical Industry Co., Ltd.)), low-polarity allyl ether phenol resin (e.g., FTC-AE (manufactured by Gunei Chemical Industry Co., Ltd.)), and allyl ether; 1-propenyl compounds having a 1-propenyl group such as propenylated biphenylene resin (e.g., BPN (manufactured by Gunei Chemical Industry Co., Ltd.)), and benzoxazine compounds. As the surfactant, for example, a fluorine surfactant or a silicone surfactant is preferably used.

Specific examples of the fluorine surfactant include commercially available fluorine surfactants such as BM-1000 and BM-1100 (both are manufactured by BM Chemie), Megaface F142D, Megaface F172, Megaface F173, and Megaface F183 (all of which are manufactured by DIC Corporation), Fluorad FC-135, Fluorad FC-170C, Fluorad FC-430, and Fluorad FC-431 (all of which are manufactured by Sumitomo 3M Limited), Surflon S-112, Surflon S-113, Surflon S-131, Surflon S-141, and Surflon S-145 (all of which are manufactured by Asahi Glass Co., Ltd), and SH-28PA, SH-190, SH-193, SZ-6032, and SF-8428 (all of which are manufactured by Toray Silicone Co., Ltd.), but are not limited thereto.

As the silicone surfactant, an unmodified silicone surfactant, a polyether-modified silicone surfactant, a polyester-modified silicone surfactant, an alkyl-modified silicone surfactant, an aralkyl-modified silicone surfactant, a reactive silicone surfactant, and the like are preferably used.

As the silicone surfactant, a commercially available silicone surfactant may be used. Specific examples of the commercially available silicone surfactant include Paintad M (manufactured by Dow Corning Toray Co., Ltd.), TOPICA K1000, TOPICA K2000, and TOPICA K5000 (all of which are manufactured by TAKACHIHO SANGYO CO., LTD.), XL-121 (a polyether-modified silicone surfactant, manufactured by Clariant), and BYK-310 (a polyester-modified silicone surfactant, manufactured by BYK Chemie).

The first curable composition may contain an antioxidant. As the antioxidant, a conventionally known antioxidant may be used without particular limitation, and examples thereof include hindered phenol antioxidants (e.g., Irganox 1010 (manufactured by BASF)), hindered amine antioxidants, phosphorus antioxidants, and sulfur antioxidants.

The first curable composition may contain a polymerization inhibitor to appropriately prevent polymerization during a reaction. As the polymerization inhibitor, a conventionally known polymerization inhibitor may be used without particular limitation, and examples thereof include methoquinone, hydroquinone, methylhydroquinone, p-methoxyphenol, pyrogallol, tert-butylcatechol, and phenothiazine.

The first curable composition may contain an adhesion improving agent to improve the adhesion between a substrate for electrical and electronic devices having metal wiring and the insulating film to be formed by using the first curable composition. As the adhesion improving agent, a conventionally known adhesion improving agent may be used without particular limitation, and examples thereof include benzotriazole.

### [Preparation Method of First Curable Composition]

The first curable composition is prepared by mixing and stirring the above components by an ordinary method. Examples of the apparatus that can be used when the above components are mixed and stirred include a dissolver, a homogenizer, and a three-roll mill. After the above components are uniformly mixed, the obtained mixture may further be filtered using a mesh, a membrane filter, or the like.

### <Second Curable Composition>

The second curable composition includes the terminally maleimide-modified polyphenylene ether resin (A) and the radical generator (C), like the first curable composition. Applications of the second curable composition are not particularly limited. The second curable composition is applicable to various applications to which conventionally known negative photosensitive resin compositions are applied. As the application of the second curable composition, the insulating film formation application is preferable, like the first curable composition.

The terminally maleimide-modified polyphenylene ether resin (A) used in the second curable composition is the same as the terminally maleimide-modified polyphenylene ether resin described with respect to the first curable resin composition, except that the linking group present between the terminal group represented by the formula (a1) and an oxygen atom derived from the phenolic hydroxyl group included in the unmodified polyphenylene ether resin (A′) is not particularly limited.

In addition, the radical generator (C) used in the second curable composition is the aforementioned photoradical generator (C1).

Optional components that may be included in the second curable composition are the same as the optional components that may be included in the first curable composition. The content of the components in the second curable composition is the same as the content of the components in the first curable composition.

### <Method for Forming Insulating Film>

An insulating film is formed by using the first curable composition or the second curable composition. Hereinafter, the generic term of the first curable composition and the second curable composition is referred to as the “curable composition”.

The method for forming an insulating film includes:
a coating step of coating a site where an insulating film is to be formed with the curable composition to form a coating film; and
a curing step of curing the coating film.

Preferably, an insulating film that insulates metal wiring in electrical and electronic devices having metal wiring can be formed by using the curable composition.

In the method for forming an insulating film, for example, at least a site where an insulating film is to be formed on the substrate for electrical and electronic devices having metal wiring is coated with the curable composition to form a coating film.

As the coating method of the curable composition, methods such as spin coating, slit coating, roll coating, screen printing, ink jetting, and applicator may be employed. When a printing method such as screen printing and ink jetting is applied, only a site where an insulating film is to be formed can be coated with the curable composition.

The thickness of the coating film is not particularly limited, but is preferably 0.5 μm or more, more preferably 0.5 μm or more and 300 μm or less, particularly preferably 1 μm or more and 150 μm or less, and most preferably 3 μm or more and 50 μm or less.

Then, if necessary, the coating film is subjected to drying or prebaking. The prebaking conditions vary depending on the type of components, blending ratio, coating film thicknesses, and the like in the curable composition, but are typically 70° C. or more and 200° C. or less, preferably 80° C. or more and 150° C. or less, and about 2 minutes or more and 120 minutes or less.

When the curable composition includes the photoradical generator (C1), the coating film is irradiated with (exposed to) active light or radiation, for example, with ultraviolet rays or visible light having a wavelength of 300 nm or more 500 nm or less. Exposure may be carried out to the entire surface of the coating film, or position-selective exposure (pattern exposure) may be carried out by a method of, for example, exposing active light or radiation via a mask having a predetermined pattern.

The resin (A) and the radically polymerizable compound (B) which are polymerization components are polymerized by exposure, so that an insulating film is formed. As a result, an insulating film is formed, for example, on a substrate for electrical and electronic devices having metal wiring.

As the light source of the radiation, a low-pressure mercury lamp, a high pressure mercury lamp, an extra-high pressure mercury lamp, a metal halide lamp, an argon gas laser, or the like may be used. The radiation includes microwaves, infrared rays, visible light, ultraviolet rays, X-rays, γ-rays, electron beams, proton beams, neutron beams, ion beams, and the like. The amount of radiation irradiated varies depending on the composition of the curable composition, the film thickness of the coating film, and the like, but is, for example, 100 mJ/cm² or more and 10,000 mJ/cm² or less when an extra-high pressure mercury lamp is used. To generate radicals, a light that activates the radical generator (C) may be included in the radiation.

In the case of position-selective exposure, the coating film exposed is developed according to a conventionally known method, an unnecessary portion is dissolved and removed, thereby forming an insulating film having a predetermined shape. At this time, the organic solvent(S) and the alkaline aqueous solution described above may be used as a developing solution. For example, when the aforementioned terminally maleimide-modified polyphenylene ether resin (A) has an alkali-soluble group such as a carboxy group and a phenolic hydroxyl group, development by an alkaline aqueous solution is possible.

As the alkaline aqueous solution used as the developing solution, for example, an aqueous solution of an alkali such as sodium hydroxide, potassium hydrate, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide (tetramethyl ammonium hydroxide), tetraethylammonium hydroxide, pyrrole, piperidine, 1,8-diazabicyclo[5,4,0]-7-undecene, and 1,5-diazabicyclo[4,3,0]-5-nonane may be used. In addition, an aqueous solution obtained by adding an appropriate amount of a water-soluble organic solvent such as methanol and ethanol or a surfactant to the above aqueous solution of an alkali may also be used as the developing solution.

The development time varies depending on the composition of the curable composition, the film thickness of the coating film, and the like, but is usually 1 minute or more and 30 minutes or less. The development method may be any of a liquid-filling method, a dipping method, a puddle method, a spray development method, and the like.

After development, for example, washing with running water is carried out for 30 seconds or more and 90 seconds or less, and drying is carried out using an air gun, an oven, or the like.

In this way, for example, an insulating film patterned into a desired shape is formed on the substrate for electrical and electronic devices having metal wiring.

Hereinbefore, an example of forming an insulating film through polymerization of the resin (A) and the radically polymerizable compound (B) which are polymerization components by exposure are described. When the curable composition includes the thermal radical generator (C2), the resin (A) and the radically polymerizable compound (B) which are polymerization components may be polymerized by heating to form an insulating film.

The insulating film formed has a low dielectric constant and a low dielectric loss tangent, and is thus suitable as the insulating film of electrical and electronic devices having metal wiring for high frequency applications. For example, the insulating film formed may be used as the insulating film of electrical and electronic devices having metal wiring for frequencies of 3 GHz or more and 30 GHz or less for a 5G communication band candidate or for millimeter wave band frequencies of 30 GHz or more and 300 GHz or less. In addition, the insulating film formed has excellent heat resistance, and is thus suitable for the application in which an insulating film is formed and then heated, and further, a member such as wiring is formed.

### EXAMPLES

Hereinafter, the present invention will be described further in detail by way of Examples, but the present invention is not limited to these Examples.

### Preparation Example 1

As the unmodified polyphenylene ether resin (A′), a polyphenylene ether resin having a phenolic hydroxyl group terminal of the following structure (SA90, manufactured by SABIC Innovative Plastics) was used.

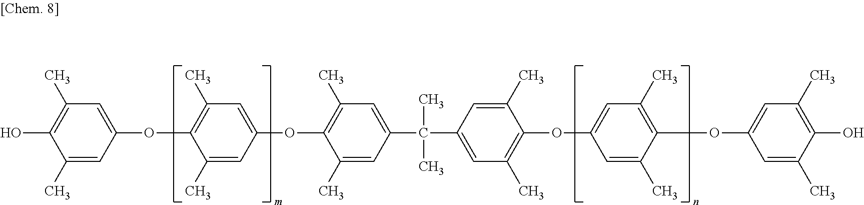

To 1, 184 parts by mass of dichloroethane, 166 parts by mass of the unmodified polyphenylene ether resin (A′) and 47.2 parts by mass of a carboxylic acid having a maleimide group of the following structure were added.

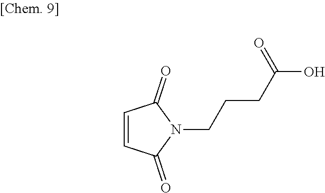 [SMILES: O=C(O)CCCN1C(=O)C=CC1=O]

Into the reaction liquid, 40.9 parts by mass of diisopropylcarbodiimide and 0.25 parts by mass of dimethylaminopyridine were added, and then, a modification reaction of the terminal phenolic hydroxyl group was carried out at 5° C. for 8 hours. After the reaction, the reaction liquid was filtrated and reprecipitated with acetonitrile to obtain 145 parts by mass of a terminally maleimide-modified polyphenylene ether resin P1 (resin P1) in which the phenolic hydroxyl groups at both terminals of the unmodified polyphenylene ether resin (A′) were modified with a group of the following formula. The mass average molecular weight (Mw) in terms of polystyrene of the terminally maleimide-modified polyphenylene ether resin P1 measured by gel permeation chromatography (GPC) was 7,000.

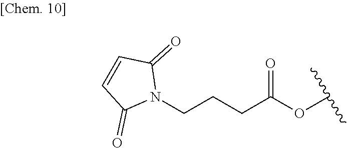 [SMILES: *OC(=O)CCCN1C(=O)C=CC1=O]

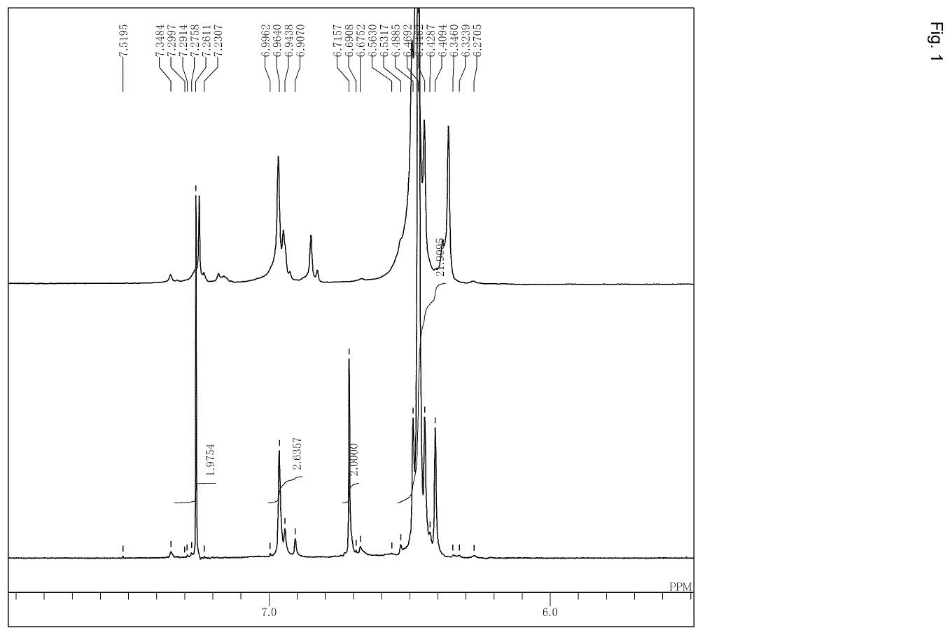

The obtained terminally maleimide-modified polyphenylene ether resin P1 and the polyphenylene ether resin (SA90) were subjected to 1H NMR measurement using deuterated chloroform as a measuring solvent. The results of the 1H NMR measurement are shown in FIG. 1. In FIG. 1, the upper spectrum is the measurement result of the polyphenylene ether resin (SA90) and the lower spectrum is the measurement result of the terminally maleimide-modified polyphenylene ether resin P1.

According to FIG. 1, the peak at 6.7 ppm derived from the maleimide skeleton is present in the lower spectrum and not present in the upper spectrum, and it is thus found that the terminally maleimide-modified polyphenylene ether resin P1 is the desired terminally maleimide-modified resin.

### Preparation Example 2

The modification reaction of the terminal phenolic hydroxyl group was carried out in the same manner as in Preparation Example 1, except that the carboxylic acid having a maleimide group was changed to 43.6 parts by mass of a compound of the following structure.

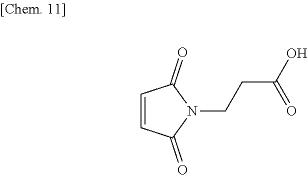 [SMILES: O=C(O)CCN1C(=O)C=CC1=O]

126 parts by mass of the terminally maleimide-modified polyphenylene ether resin P2 (resin P2) in which the phenolic hydroxyl groups at both terminals of the unmodified polyphenylene ether resin (A′) were modified with a group of the following formula was obtained. The mass average molecular weight (Mw) in terms of polystyrene of the terminally maleimide-modified polyphenylene ether resin P2 measured by gel permeation chromatography (GPC) was 7,000.

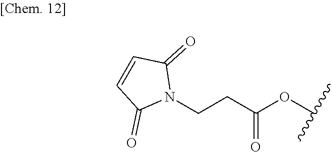 [SMILES: *OC(=O)CCN1C(=O)C=CC1=O]

### Preparation Example 3

The modification reaction of the terminal phenolic hydroxyl group was carried out in the same manner as in Preparation Example 1 except that the carboxylic acid having a maleimide group was changed to 57.0 parts by mass of a compound of the following structure.

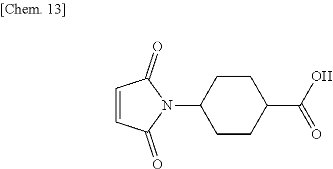 [SMILES: O=C(O)C1CCC(N2C(=O)C=CC2=O)CC1]

140 parts by mass of the terminally maleimide-modified polyphenylene ether resin P3 (resin P3) in which the phenolic hydroxyl groups at both terminals of the unmodified polyphenylene ether resin (A′) were modified with a group of the following formula was obtained. The mass average molecular weight (Mw) in terms of polystyrene of the terminally maleimide-modified polyphenylene ether resin P3 measured by gel permeation chromatography (GPC) was 7,000.

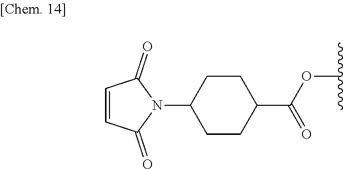 [SMILES: *OC(=O)C1CCC(N2C(=O)C=CC2=O)CC1]

### <Preparation of Curable Composition>

### Examples 1 to 9, and Comparative Examples 1 to 7

In Examples 1 to 9, the above resins P1 to P3 were used as the resin (A). In Examples 1 to 9 and Comparative Examples 1 to 7, the following B1 to B5 and B6: SA9000 (manufactured by SABIC Innovative Plastics, a modified polyphenylene ether in which the terminal hydroxyl group of polyphenylene ether was modified with a methacryl group) were used as the radically polymerizable compound (B). Note that B1 is BMI-689 and B2 is BMI-3000 (both are manufactured by Designer molecules Inc.).

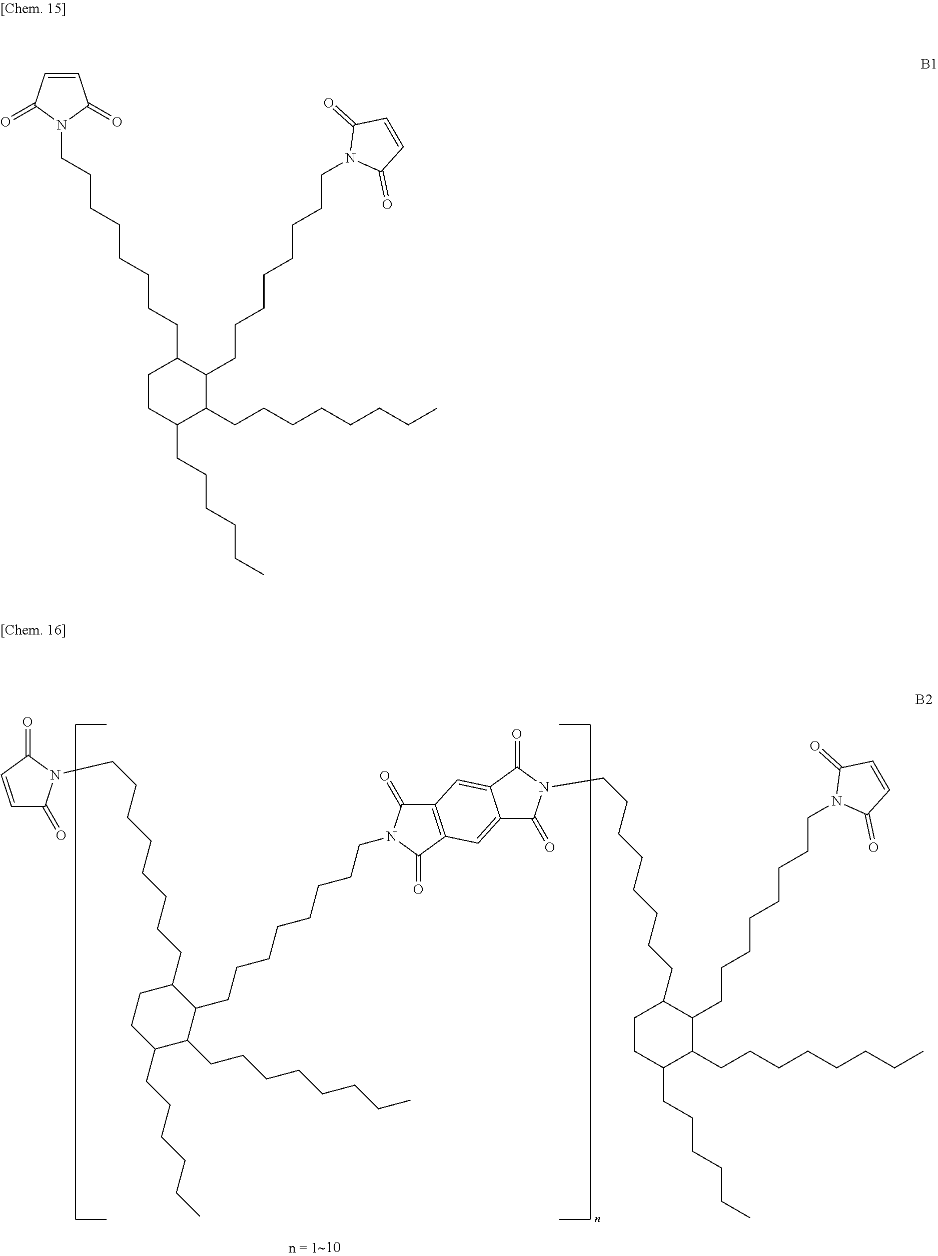

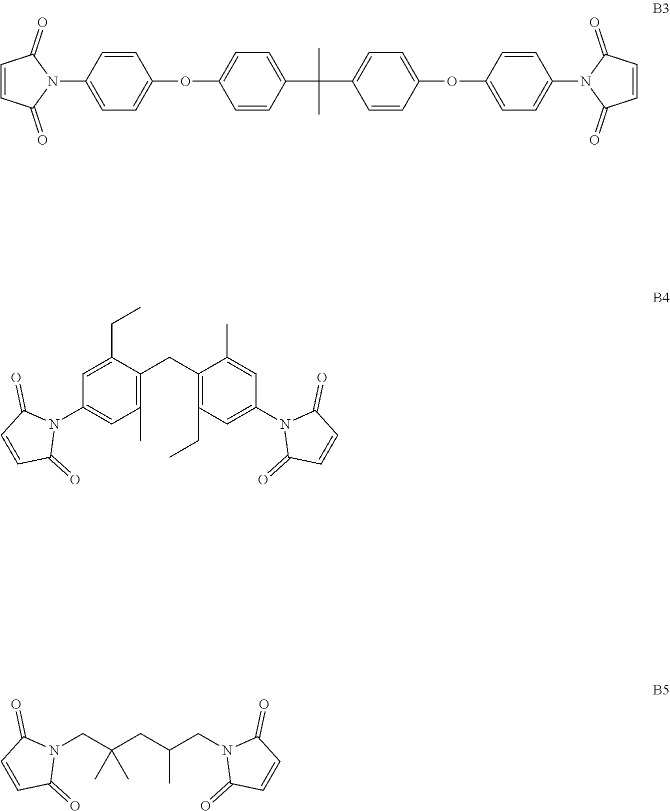 [SMILES: CC(C)(c1ccc(Oc2ccc(N3C(=O)C=CC3=O)cc2)cc1)c1ccc(Oc2ccc(N3C(=O)C=CC3=O)cc2)cc1 ; CCc1cc(N2C(=O)C=CC2=O)cc(C)c1Cc1c(C)cc(N2C(=O)C=CC2=O)cc1CC ; CC(CN1C(=O)C=CC1=O)CC(C)(C)CN1C(=O)C=CC1=O]

In Examples 1 to 9 and Comparative Examples 1 to 7, the following C1 to C4 were used as the radical generator (C).
C1: Irgacure OXE01 (manufactured by BASF)
C2: Irgacure OXE02 (manufactured by BASF)
C3: Omnirad 819 (manufactured by IGM Resins B.V.)
C4: Perhexyl D (manufactured by NOF CORPORATION)

In Examples 1 to 9 and Comparative Examples 1 to 7, the following D1 to D3 and a surfactant (BYK310, manufactured by BYK Chemie) were used as the additive.

D1: Irganox 1010 (manufactured by BASF)
D2: Methoquinone
D3: Benzotriazole

The terminally maleimide-modified polyphenylene ether resin (resin (A)) and/or the radically polymerizable compound (B), the radical generator (C), and the additive, the kinds and amounts of which are described in Tables 1 to 2, and 0.05 parts by mass of a surfactant (BYK310, manufactured by BYK Chemie) were dissolved in propylene glycol monomethyl ether acetate (PGMEA) such that the solid concentration was 40% by mass, whereby the curable compositions of Examples and Comparative Examples were obtained.

### <Evaluation>

By using the obtained curable compositions, film formation properties, photolithographic properties, dielectric constant, dielectric loss tangent, and heat resistance were evaluated according to the following methods. These evaluation results are shown in Table 1 to 2.

### [Film Formation Properties and Photolithographic Properties]

A Si substrate having a diameter of 200 mm was coated with each of the curable compositions of Examples and Comparative Examples to form a coating film. Then, the coating film was prebaked (PAB) at 80° C. for 200 seconds. Note that the film thickness of the coating film after prebaking was 11 μm. After prebaking, pattern exposure with a ghi line was carried out at an exposure amount of 100 mJ/cm² or more and 4, 400 mJ/cm² or less using a mask with a hole pattern capable of forming a circular opening having a diameter of 30 μm and an exposure apparatus Prisma GHI5452 (manufactured by Ultratech, Inc.). Note that the focus was 0 μm (coating film surface).

Then, the substrate was placed on a hot plate and subjected to post exposure baking (PEB) at 90° C. for 1.5 minutes. Thereafter, the exposed coating film was immersed in propylene glycol monomethyl ether acetate (PGMEA) at 60° C. for 60 seconds. Thereafter, the obtained product was blown with nitrogen and heated under nitrogen atmosphere at 180° C. for 1 hour to obtain a pattern (insulating film).

The surface of the coating film before prebaking was observed with a scanning electron microscope and the film formation properties was evaluated. Specifically, a case where no crack and/or no crystal was observed on the pattern surface, and no tackiness (stickiness) was present on the pattern, and the contained components were compatible and transparent was evaluated as good. A case where crack was observed on the pattern surface was evaluated as a, a case where crystal was observed on the pattern surface was evaluated as b, a case where tackiness (stickiness) was present on the pattern surface was evaluated as c, and a case where the contained components were not compatible and opaque was evaluated as d.

Also, the surface and cross-section surface of the obtained pattern (insulating film) were observed with a scanning electron microscope and the photolithographic properties were evaluated. Specifically, in the aforementioned range of the exposure amount, a case where conditions for forming an opening having a diameter of 30 μm were present was evaluated as good, and when conditions for forming an opening having a diameter of 30 μm were not present was evaluated as poor.

Since Comparative Example 1 had tackiness and no pattern (insulating film) was formed, dielectric constant, dielectric loss tangent, and heat resistance were not evaluated.

Since, in Comparative Examples 3 and 4, cracks and crystals were generated on the coating film before prebaking, photolithographic properties, dielectric constant, dielectric loss tangent, and heat resistance were not evaluated.

### [Dielectric Constant and Dielectric Loss Tangent]

A Si substrate having a diameter of 200 mm was coated with each of the curable compositions of Examples and Comparative Examples to form a coating film. Then, the coating film was prebaked (PAB) at 80° C. for 200 seconds. Note that the film thickness of the coating film after prebaking was 11 μm. After prebaking, the entire surface was exposed with a ghi line at an exposure amount of 4,400 mJ/cm² using an exposure apparatus Prisma GHI5452 (manufactured by Ultratech, Inc.). Note that the focus was 0 μm (coating film surface). Thereafter, the coating film surface was blown with nitrogen and heated under nitrogen atmosphere at 180° C. for 1 hour to obtain a sample.

The dielectric constant (8) and the dielectric loss tangent (tan δ) of the obtained sample were measured by a method described in Technical Report of the Institute of Electronics, Information, and Communication Engineers vol. 118, no. 506, MW2018-158, pp. 13-18, March 2019, “A study on millimeter wave complex permittivity evaluations by the circular empty cavity method for photosensitive insulator” (Kouhei Takahagi (Utsunomiya University), Kazuaki Ebisawa (TOKYO OHKA KOGYO CO., LTD.), Yoshinori Kogami (Utsunomiya University), Takashi Shimizu (Utsunomiya University)). Measurement was made by using a network analyzer HP8510C (manufactured by Keysight Technologies) by a cavity resonator method under conditions of room temperature of 25° C., humidity of 50%, frequency of 36 GHZ, and sample thickness of 10 μm.

The dielectric constant was evaluated by determining a case where the dielectric constant value was less than 3.00 as good and a case where the dielectric constant value was 3.00 or more as poor.

The dielectric loss tangent was evaluated by determining a case where the dielectric loss tangent value was less than 0.01 as good and a case where the dielectric loss tangent value was 0.01 or more as poor.

### [Heat Resistance]

With respect to the sample obtained in the same manner as in the item [Dielectric Constant and Dielectric Loss Tangent], a peak top temperature (° C.) of tan δ measured using a dynamic viscoelasticity measurement apparatus Rheogel-E4000 (manufactured by Universal Building Materials Co., Ltd.) was made to be the glass transition temperature (Tg) (DMA method). The measurement conditions were as follows: measurement mode: tension mode, frequency: 10 Hz, temperature rising rate: 5° C./min, measurement temperature range: 40 to 300° C., sample shape: 50 mm in length, 5 mm in width, and 10 μmm in thickness.

Heat resistance was evaluated by determining a case where Tg was 150° C. or more as good, and a case where Tg was less than 150° C. as poor.

TABLE 1

| | | Radically | | | | | | | |
|---|---|---|---|---|---|---|---|---|---|
| | | polymerizable | Radical | | | | | | |
| | Resin | compound | generator | | Evaluation | | | | |
| | (A) | (B) | (C) | Additive | Film | Photo- | | Dielectric | |
| | Type/part | Type/part | Type/part | Type/part | formation | lithographic | Dielectric | loss | Heat |
| | by mass | by mass | by mass | by mass | properties | properties | constant | tangent | resistance |
| Example 1 | P1/60 | B1/40 | C2/5 | D1/0.1 | good | good | good | good | good |
| Example 2 | P2/60 | | C4/1 | | good | good | good | good | good |
| Example 3 | P3/60 | | | | good | good | good | good | good |
| Example 4 | P1/80 | B1/20 | C1/1 | D2/0.1 | good | good | good | good | good |
| Example 5 | P2/80 | B1/20 | C3/5 | D3/0.05 | good | good | good | good | good |
| Example 6 | P3/80 | B1/20 | C4/1 | | good | good | good | good | good |
| Example 7 | P2/80 | B5/20 | | | good | good | good | good | good |
| Example 8 | P2/80 | B4/10 | | | good | good | good | good | good |
| | | B5/10 | | | | | | | |
| Example 9 | P2/80 | B3/10 | | | good | good | good | good | good |
| | | B5/10 | | | | | | | |

TABLE 2

| | | Radically | | | | | | | |
|---|---|---|---|---|---|---|---|---|---|
| | | polymerizable | Radical | | | | | | |
| | Resin | compound | generator | | Evaluation | | | | |
| | (A) | (B) | (C) | Additive | Film | Photo- | | Dielectric | |
| | Type/part | Type/part | Type/part | Type/part | formation | lithographic | Dielectric | loss | Heat |
| | by mass | by mass | by mass | by mass | properties | properties | constant | tangent | resistance |
| Comparative | — | B1/100 | C2/3 | D2/ | c | poor | — | — | — |
| Example 1 | | | C4/1 | 0.05 | | | | | |
| Comparative | — | B2/100 | | | good | good | good | good | poor |
| Example 2 | | | | | | | | | |
| Comparative | — | B3/100 | | | a | — | — | — | — |
| Example 3 | | | | | | | | | |
| Comparative | — | B4/100 | | | b | — | — | — | — |
| Example 4 | | | | | | | | | |
| Comparative | — | B2/50 | | | d | poor | good | good | poor |
| Example 5 | | B3/50 | | | | | | | |
| Comparative | — | B2/50 | | | d | poor | good | good | poor |
| Example 6 | | B4/50 | | | | | | | |
| Comparative | — | B2/50 | | | d | poor | good | good | poor |
| Example 7 | | B5/50 | | | | | | | |

According to Examples 1 to 9, it is found that the curable composition including the terminally maleimide-modified polyphenylene ether resin (A) having the group represented by the formula (a1) at a terminal of the molecular chain, and the radical generator (C) can form an insulating film having a low dielectric constant and a low dielectric loss tangent as well as excellent heat resistance, and also has excellent film formation properties. In the compositions of Examples 1 to 9, the terminally maleimide-modified polyphenylene ether resin (A) was dissolved in PGMEA. According to Examples 1 to 9, it is also found that the above curable composition also has excellent photolithographic properties.

On the other hand, according to Comparative Examples 1 to 7, it is found that, when the curable composition contains no terminally maleimide-modified polyphenylene ether resin (A), it is difficult to achieve both formation of an insulating film having a low dielectric constant and a low dielectric loss tangent as well as excellent heat resistance, and good film formation properties.

### Examples 10 to 12

In Example 10, a curable composition having the same components and amounts blended as Example 1 was prepared, as shown in Table 3, except that anisole was used as the organic solvent instead of PGMEA, and the obtained curable composition was evaluated in the same manner as in Example 1.

In Examples 11 and 12, each of FATC and FTC-AE (both are manufactured by Gunei Chemical Industry Co., Ltd.) was mixed as the maleimide curing agent (E) which is an additive in Example 10 in an amount blended shown in Table 3 to prepare a curable composition, and the obtained curable composition was evaluated in the same manner as in Example 1. Note that FATC is represented by the following E1, and FTC-AE is represented by the following E2.

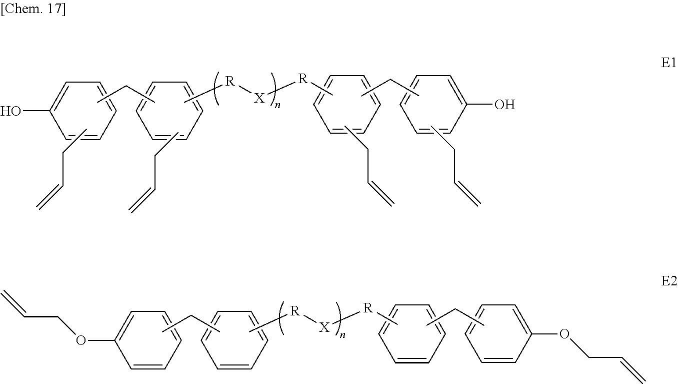

TABLE 3

| | | Radically | | | | | | | |
|---|---|---|---|---|---|---|---|---|---|
| | | polymerizable | Radical | | | | | | |
| | Resin | compound | generator | | Evaluation | | | | |
| | (A) | (B) | (C) | Additive | Film | Photo- | | Dielectric | |
| | Type/part | Type/part | Type/part | Type/part | formation | lithographic | Dielectric | loss | Heat |
| | by mass | by mass | by mass | by mass | properties | properties | constant | tangent | resistance |
| Example 10 | P1/60 | B1/40 | C2/5 | D1/0.1 | good | good | good | good | good |
| Example 11 | | | C4/1 | D1/0.1 | good | good | good | good | good |
| | | | | E1/20 | | | | | |
| Example 12 | | | | D1/0.1 | good | good | good | good | good |
| | | | | E2/20 | | | | | |

In the composition of Example 10, the terminally maleimide-modified polyphenylene ether resin (A) was dissolved in anisole. In addition, it is found that the composition of Example 10 can form an insulating film that has a low dielectric constant and a low dielectric loss tangent, excellent heat resistance, and excellent photolithographic properties, and also has excellent film formation properties like Example 1. In addition, the compositions of Examples 11 and 12 in which the maleimide curing agent (E) was blended as the additive showed similar results as the composition of Example 10.

What is claimed is:

1. A method for forming an insulating film comprising:
coating a site where an insulating film is to be formed with a curable composition to form a coating film; and
curing the coating film,
wherein the curable composition comprises a terminally maleimide-modified polyphenylene ether resin (A) and a radical generator (C),
wherein the terminally maleimide-modified polyphenylene ether resin (A) has, at a terminal of a molecular chain, a terminal group represented by the following formula (a1): 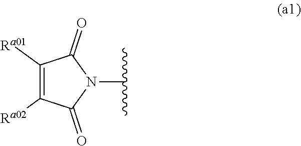
wherein R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms;
a phenylene group in a main chain of the terminally maleimide-modified polyphenylene ether resin (A) optionally has 1 or more and 4 or less substituents;
wherein the terminal group is bonded to the main chain of the terminally maleimide-modified polyphenylene ether resin (A) via a linking group represented by the following formula (a2):
$$⋆ - {Y}^{2} - {Y}^{1} - ⋆ ⋆ \qquad ( a2 )$$
wherein the bond on the ** side in the linking group is bonded to an oxygen atom derived from a hydroxyl group at a terminal of a molecular chain of an unmodified polyphenylene ether resin (A′) yielding the terminally maleimide-modified polyphenylene ether resin (A),
the bond on the * side in the linking group is bonded to the terminal group, and
Y¹ is a single bond or a carbonyl group, Y² is a divalent organic group, and when Y¹ is a single bond, the single bond as Y¹ is bonded to a carbon atom having an sp3 hybrid orbital in the divalent organic group as Y².

2. A method for forming an insulating film comprising:
coating a site where an insulating film is to be formed with a curable composition to form a coating film; and
curing the coating film,
wherein the curable composition comprises a terminally maleimide-modified polyphenylene ether resin (A) and a radical generator (C),
wherein the terminally maleimide-modified polyphenylene ether resin (A) has, at a terminal of a molecular chain, a terminal group represented by the following formula (a1): 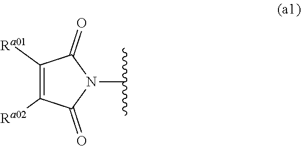
wherein R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms;
a phenylene group in a main chain of the terminally maleimide-modified polyphenylene ether resin (A) optionally has 1 or more and 4 or less substituents; and
the radical generator (C) is a photoradical generator (C1).

3. The method for forming an insulating film according to claim 2, wherein the terminal group is bonded to the main chain of the terminally maleimide-modified polyphenylene ether resin (A) via a linking group represented by the following formula (a2):
$$⋆ - {Y}^{2} - {Y}^{1} - ⋆ ⋆ \qquad ( a2 )$$
wherein the bond on the ** side in the linking group is bonded to an oxygen atom derived from a hydroxyl group at a terminal of a molecular chain of an unmodified polyphenylene ether resin (A′) yielding the terminally maleimide-modified polyphenylene ether resin (A),
the bond on the * side in the linking group is bonded to the terminal group, and
Y¹ is a single bond or a carbonyl group, Y² is a divalent organic group, and when Y¹ is a single bond, the single bond as Y¹ is bonded to a carbon atom having an sp3 hybrid orbital in the divalent organic group as Y².

4. The method for forming an insulating film according to claim 1, wherein, in the formula (a2), Y¹ is a carbonyl group, Y² is a group represented by —Y⁴—Y³—, Y³ is a single bond, —O—, or —NH—, Y⁴ is a divalent organic group, and Y³ is bonded to the carbonyl group as Y¹.

5. The method for forming an insulating film according to claim 4, wherein Y³ is a single bond, and Y⁴ is a divalent hydrocarbon group having 1 or more and 10 or less carbon atoms.

6. The method for forming an insulating film according to claim 1, wherein the curable composition further comprises a radically polymerizable monomer (B).

7. The method for forming an insulating film according to claim 6, wherein the radically polymerizable monomer (B) comprises a radically polymerizable compound having a group represented by the formula (a1).

8. The method for forming an insulating film according to claim 1, wherein the curable composition comprises a photoradical generator (C1) as a radical generator (C), and the coating film is cured by exposure.

9. The method for forming an insulating film according to claim 8, wherein the exposure of the coating film is performed position-selectively, and
the method further comprises developing the exposed coating film with a developing solution.
